(19) United States
(12) Patent Application Publication
(10) Pub. No.: US 2021/0407800 A1
(43) Pub. Date: Dec. 30, 2021

(54) METHOD FOR MANUFACTURING DEPOSITION MASK, METHOD FOR MANUFACTURING DISPLAY DEVICE, AND DEPOSITION MASK INTERMEDIATE

(71) Applicant: TOPPAN INC., Tokyo (JP)

(72) Inventors: Mikio SHINNO, Tokyo (JP); Reiji TERADA, Tokyo (JP); Kenta TAKEDA, Tokyo (JP); Akihiko KOBAYASHI, Tokyo (JP)

(21) Appl. No.: 17/475,287

(22) Filed: Sep. 14, 2021

Related U.S. Application Data
(63) Continuation of application No. PCT/JP2020/011025, filed on Mar. 13, 2020.

(30) Foreign Application Priority Data
Mar. 15, 2019 (JP) 2019-049161
Nov. 15, 2019 (JP) 2019-207310

(51) Int. Cl. H01L 21/033; H01L 51/56; C23C 16/04; H01L 51/00; H01L 21/67

(52) U.S. Cl. CPC H01L 21/0334; H01L 51/56; H01L 21/67248; H01L 51/0011; C23C 16/042

(57) ABSTRACT

A method includes: preparing a metal sheet and a glass substrate in which an absolute value of a difference in linear expansion coefficient between the glass substrate and the metal sheet is less than or equal to 1.3×10⁻⁶/° C. in a temperature range between 25° C. and 100° C. inclusive; joining the glass substrate to the metal sheet with a plastic layer in between; forming a mask plate from the metal sheet by forming mask holes in the metal sheet joined to the glass substrate; joining, to a mask frame, a surface of the mask plate that is opposite to a surface in contact with the plastic layer, the mask frame having a higher rigidity than the mask plate and having a shape that surrounds the entire mask holes; and removing the plastic layer and the glass substrate from the mask plate joined to the mask frame.

### BACKGROUND

The present disclosure relates to a method for manufacturing a vapor deposition mask, a method for manufacturing a display device, and a vapor deposition mask intermediate.

The electroluminescent (EL) elements of an organic EL device are formed by vapor deposition. To form the EL elements, a vapor deposition mask is used to pattern functional layers of the EL elements. The vapor deposition mask includes mask plates and a common frame to which each mask plate is attached. The frame has a rectangular shape that surrounds a vapor deposition target. Each mask plate is a metal foil that has the shape of a planar strip. The mask plate includes mask regions spaced apart from one another in the direction in which the mask plate extends. Each mask region includes through-holes in correspondence with the pattern of the functional layer. In each mask plate, the region outside of the mask region is a surrounding region. The surrounding region surrounds the mask region. Each mask plate is fixed to the frame such that the mask regions are located in the region surrounded by the frame. The direction in which the mask regions are laid out is a longitudinal direction. Each mask plate is fixed to the frame in the surrounding region located at the opposite ends in the longitudinal direction (refer to, for example, Japanese Laid-Open Patent Publication No. 2018-127721).

In the vapor deposition mask, for example, the position of a pattern for the vapor deposition target needs to be increased in accuracy. Thus, in the vapor deposition mask, a technique is used in mask holes formed in the mask plate to monotonically decrease the passage area of each mask hole from a first opening, which faces a vapor deposition source, toward a second opening, which faces the vapor deposition target. The passage area is the area of the mask hole in each plane parallel to a plane where the vapor deposition mask extends. It has recently been desired that the distance between the first opening and the second opening (i.e., the thickness of the mask plate) be reduced in order to increase the uniformity of the thickness of a pattern.

When the mask plate has a small thickness, the mechanical resistance of the mask plate may not be sufficiently obtained. This makes handling the mask plate extremely difficult. Thus, the above-described mask plate strongly needs a technique that improves the handleability of the mask plate.

### SUMMARY

It is an objective of the present disclosure to provide a method for manufacturing a vapor deposition mask, a method for manufacturing a display device, and a vapor deposition mask intermediate that improve the handleability of a mask plate.

To solve the above-described problem, a method for manufacturing a vapor deposition mask from a metal sheet made of iron-nickel alloy is provided. The vapor deposition mask includes a mask plate with mask holes. The method includes: preparing the metal sheet and a glass substrate in which an absolute value of a difference between a linear expansion coefficient of the glass substrate and a linear expansion coefficient of the metal sheet is less than or equal to 1.3×10⁻⁶/° C. in a temperature range between 25° C. and 100° C. inclusive; joining the glass substrate to the metal sheet with a plastic layer in between; forming the mask plate from the metal sheet by forming the mask holes in the metal sheet joined to the glass substrate; joining, to a mask frame, a surface of the mask plate that is opposite to a surface in contact with the plastic layer, the mask frame having a higher rigidity than the mask plate and having a shape that surrounds the entire mask holes; and removing the plastic layer and the glass substrate from the mask plate joined to the mask frame.

The method for manufacturing the display device that solves the above-described problem includes forming a pattern on a vapor deposition target using the vapor deposition mask manufactured by the method for manufacturing the vapor deposition mask.

A vapor deposition mask intermediate that solves the above-described problem includes: an iron-nickel alloy mask plate with mask holes, the mask plate including a first surface and a second surface opposite to the first surface; a mask frame that having a higher rigidity than the mask plate and having a shape that surrounds the entire mask holes in the mask plate, the mask frame being joined to the first surface of the mask plate; a plastic layer joined to the second surface of the mask plate; and a glass substrate joined to the plastic layer. An absolute value of a difference between a linear expansion coefficient of the glass substrate and a linear expansion coefficient of the metal sheet is less than or equal to 1.3×10⁻⁶/° C. in a temperature range between 25° C. and 100° C. inclusive.

### BRIEF DESCRIPTION OF THE DRAWINGS

FIG. 1 is a perspective view showing the structure of a vapor deposition mask according to a first example.

FIG. 2 is a cross-sectional view showing part of the structure of the vapor deposition mask in FIG. 1.

FIG. 3 is an enlarged cross-sectional view showing the structure of the mask plate of the vapor deposition mask in FIG. 2.

FIG. 4 is a plan view showing the structure of the vapor deposition mask according to a second example.

FIG. 5 is a cross-sectional view showing the structure of the vapor deposition mask in FIG. 4.

FIG. 6 is a diagram illustrating a step of the method for manufacturing the vapor deposition mask.

FIG. 7 is a diagram illustrating a step of the method for manufacturing the vapor deposition mask.

FIG. 8 is a diagram illustrating a step of the method for manufacturing the vapor deposition mask.

FIG. 9 is a diagram illustrating a step of the method for manufacturing the vapor deposition mask.

FIG. 10 is a diagram illustrating a step of the method for manufacturing the vapor deposition mask.

FIG. 11 is a diagram illustrating a step of the method for manufacturing the vapor deposition mask.

FIG. 12 is a diagram illustrating a step of the method for manufacturing the vapor deposition mask.

FIG. 13 is a diagram illustrating a step of the method for manufacturing the vapor deposition mask.

FIG. 14 is a diagram illustrating a step of the method for manufacturing the vapor deposition mask.

FIG. 15 is a diagram illustrating the operation of the vapor deposition mask.

FIG. 16 is a diagram illustrating the operation of the vapor deposition mask.

FIG. 17 is a schematic diagram showing the structure of the vapor deposition apparatus with the vapor deposition mask and the vapor deposition target.

FIG. 18 is a plan view illustrating the method for measuring a position accuracy in test examples.

### DESCRIPTION OF EXEMPLARY EMBODIMENTS

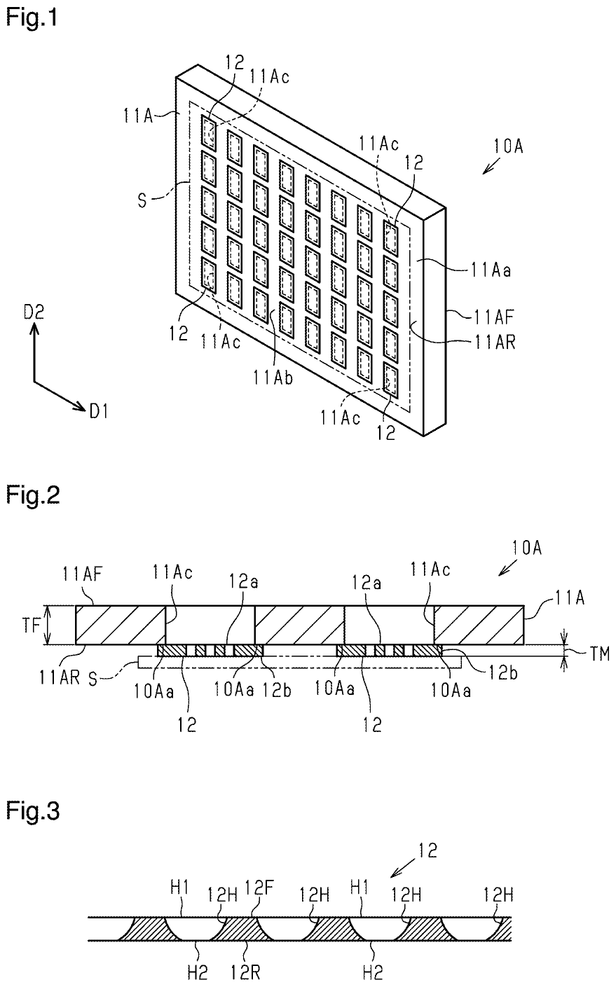

A method for manufacturing a vapor deposition mask, a method for manufacturing a display device, and a vapor deposition mask intermediate according to an embodiment will now be described with reference to FIGS. 1 to 18. In the following description, the vapor deposition mask, the method for manufacturing the vapor deposition mask, and the method for manufacturing the display device will be described in this order.

Vapor Deposition Mask

The structure of the vapor deposition mask will now be described with reference to FIGS. 1 to 5. In the following description, first, the structure of the vapor deposition mask according to a first example will be described. Then, the structure of the vapor deposition mask according to a second example will be described.

### First Example

The first example of the vapor deposition mask will now be described with reference to FIGS. 1 to 3.

As shown in FIG. 1, a vapor deposition mask 10A includes a mask frame 11A and mask plates 12. The mask frame 11A includes a frame-shaped portion 11Aa, a defining element 11Ab, and openings 11Ac. The frame-shaped portion 11Aa is located at the outer edge of the mask frame 11A and has a size and shape capable of surrounding a vapor deposition target S. The defining element 11Ab is located in a region surrounded by the frame-shaped portion 11Aa and has a grid pattern. The openings 11Ac are defined by the defining element 11Ab. In other words, the defining element 11Ab isolates the openings 11Ac from each other. Each mask plate 12 includes through-holes. The mask plates 12 are joined to the mask frame 11A such that each mask plate 12 covers one opening 11Ac.

Since the mask frame 11A includes the grid-pattern defining element 11Ab, the mask frame 11A has a higher rigidity than a frame having a rectangular shape. The mask plates 12 are directly joined one by one to the surroundings of each opening 11Ac of the mask frame 11A, which has an increased rigidity. This limits the warpage of the mask plates 12 as compared to a structure in which a structural body supporting each mask plate 12 has the shape of a straight line extending one-dimensionally in the width direction of the mask plate, which has the shape of a planar strip. As a result, the position accuracy of a pattern formed in the vapor deposition target S increases.

Since the mask frame 11A includes the grid-pattern defining element 11Ab (i.e., since the mask frame 11A has a grid pattern with a high rigidity in which the structural body supporting each mask plate 12 extends two-dimensionally), the mask frame 11A resists warping. Thus, the mask plates 12, which are directly joined to the mask frame 11A, resist warping in the same manner. In the case of a mask frame having a rectangular shape, the structural body supporting each mask plate has the shape of a straight line extending one-dimensionally in the width direction of the mask plate, which has the shape of a planar strip, and is located only at the opposite ends in the extending direction of the mask plate. This causes the mask plate to easily warp in the extending direction of the mask plate.

The outer shape of the frame-shaped portion 11Aa is rectangular. When the vapor deposition mask 10A is used in vapor deposition for the vapor deposition target S, a part of the frame-shaped portion 11Aa is located outside of the edge of the vapor deposition target S and another part of the frame-shaped portion 11Aa overlaps the vapor deposition target S in a plan view of the plane on which the vapor deposition target S extends. The mask frame 11A includes a front surface 11AF and a rear surface 11AR. In the mask frame 11A, the rear surface 11AR faces the vapor deposition target S. FIG. 1 shows the structure of the vapor deposition mask 10A in a plan view of the rear surface 11AR.

In the present embodiment, the defining element 11Ab includes a portion extending in a first direction D1 and a portion extending in a second direction D2, which is orthogonal to the first direction D1. The defining element 11Ab has a rectangular shape with a grid pattern. Thus, in the mask frame 11A, multiple openings 11Ac are laid out in the first direction D1 and multiple openings 11Ac are laid out in the second direction D2. In the directions D1 and D2, the openings 11Ac are spaced apart from one another at equal intervals. Each opening 11Ac has a rectangular shape in a plan view of the rear surface 11AR.

The openings 11Ac do not have to be spaced apart from one another at equal intervals in the first direction D1 and the second direction D2. That is, the intervals between the openings 11Ac adjacent to each other may include multiple lengths. Further, since the openings 11Ac simply need to be laid out in a grid pattern, the openings 11Ac do not need to be laid out in a rectangular grid pattern but may be laid out in a triangular grid pattern or in a hexagonal grid pattern. Additionally, the openings 11Ac may be laid out in a houndstooth pattern. The opening 11Ac does not need to have a rectangular shape. In this case, the opening 11Ac may have, for example, a square shape, a circular shape, or an oval shape. The openings 11Ac may include openings 11Ac with a first shape and openings 11Ac with a second shape.

The mask plates 12 have a shape and size capable of covering the openings 11Ac in a plan view of the rear surface 11AR of the mask frame 11A. In the present embodiment, the mask plates 12 have a rectangular shape. Each mask plate 12 is attached to the corresponding opening 11Ac. Thus, in the vapor deposition mask 10A, the number of the openings 11Ac is the same as the number of the mask plates 12.

The mask frame 11A and the mask plate 12 are made of metal. The mask frame 11A and the mask plate 12 are preferably made of the same metal. Thus, even if the vapor deposition mask 10A is heated, the mask plate 12 is unlikely to deform due to the difference in the linear expansion coefficient between the vapor deposition mask 10A and the mask plate 12. This consequently limits a decrease in the position accuracy of a pattern that is formed using the vapor deposition mask 10A.

The mask plate 12 can be made of iron-nickel alloy, which is an alloy of iron and nickel. The mask plate 12 is preferably made of, among the types of iron-nickel alloy, Invar, which is an alloy containing 36 mass % of nickel. The mask plate 12 may be made of Alloy 42, which is an alloy containing 42 mass % of nickel. In addition to iron and nickel, the mask plate 12 may contain additives, such as chromium, manganese, carbon, and cobalt.

The vapor deposition target S is preferably made of glass. In the vapor deposition target S made of glass, the difference in the linear expansion coefficient between the vapor deposition target S and the mask plate 12 is unlikely to increase when the mask plate 12 is made of Invar. The vapor deposition target S may be a laminate of a glass base plate and a plastic layer. In this case, a pattern is formed in the plastic layer of the vapor deposition target S. Alternatively, the vapor deposition target S may be a plastic film. The plastic layer and the plastic film are preferably made of, for example, polyimide plastic selected for their linear expansion coefficients.

FIG. 2 shows the structure of the cross-section of a part of the vapor deposition mask 10A along the plane that is orthogonal to the front surface 11AF and is parallel to the first direction D1.

As shown in FIG. 2, each opening 11Ac is a through-hole extending through the front surface 11AF and the rear surface 11AR of the mask frame 11A. In the example shown in FIG. 2, each opening 11Ac has a rectangular shape. In each opening 11Ac, the rectangular cross-sectional shape is continuous in the second direction D2. The cross-sectional shape of each opening 11Ac may be, for example, trapezoid or inverted trapezoid. When the cross-sectional shape of the opening 11Ac is trapezoid, the opening 11Ac is shaped such that the width of the rear surface 11AR is larger than the width of the front surface 11AF and the width of the opening 11Ac monotonically increases from the front surface 11AF toward the rear surface 11AR.

When the cross-sectional shape of the opening 11Ac is inverted-trapezoid, the opening 11Ac is shaped such that the width of the rear surface 11AR is smaller than the width of the front surface 11AF and the width of the opening 11Ac monotonically decreases from the front surface 11AF toward the rear surface 11AR. As another option, the cross-sectional shape of the opening 11Ac may be arcuate such that the center of curvature is located closer to the front surface 11AF than to the rear surface 11AR.

The thickness TF of the mask frame 11A is preferably greater than or equal to 500 μm. The thickness TF of the mask frame 11A is the thickness of the mask frame 11A in a structure along the cross-section that is orthogonal to the plane on which the mask frame 11A extends. Thus, the mask frame 11A is highly rigid because of its thickness. This allows the mask frame 11A to limit the expansion and contraction of the mask plates 12. Accordingly, the position of each through-hole relative to the vapor deposition target S is unlikely to change. As a result, the position accuracy of a pattern formed in the vapor deposition target S further increases. The thickness TM of the mask plate 12 is, for example, between 1 μm and 15 μm inclusive. The mask plate 12 includes a mask region 12a, which includes the through-holes, and a surrounding region 12b, which surrounds the mask region 12a. The thickness of the mask region 12a may be equal to or smaller than the thickness of the surrounding region 12b.

The vapor deposition mask 10A includes a joining section 10Aa, where the mask frame 11A and each mask plate 12 are joined to each other. The mask frame 11A and the mask plate 12 may be joined to each other through adhesion using adhesive arranged between the mask frame 11A and the mask plate 12 or through laser welding by irradiating the mask frame 11A and the mask plate 12 with a laser. In the case of joining the mask frame 11A and the mask plate 12 to each other using adhesive, the adhesive forms the joining section 10Aa. In the case of joining the mask frame 11A and the mask plate 12 through laser welding, the joining section 10Aa is a mark formed through the laser beam irradiation.

In a plan view of the rear surface 11AR, the joining section 10Aa may be arranged on the entire mask plate 12 in the circumferential direction or may be arranged intermittently in the circumferential direction. When the joining section 10Aa is arranged on the mask plate 12 intermittently in the circumferential direction, it is preferred that at least part of each side of the mask plate 12 be joined to the mask frame 11A.

As shown in FIG. 3, the mask plate 12 includes a front surface 12F and a rear surface 12R, which is opposite to the rear surface 12R. The front surface 12F is an example of a first surface, and the rear surface 12R is an example of a second surface. The front surface 12F faces the vapor deposition source in a vapor deposition apparatus. Part of the front surface 12F is joined to the mask frame 11A. The rear surface 12R is in contact with the vapor deposition target S in the vapor deposition apparatus.

The mask plate 12 may be formed by a single metal sheet or may be formed by multiple metal sheets. When the mask plate 12 is formed by multiple metal sheets, the metal sheets are laminated in the thickness direction of the mask plate 12. The mask plate 12 includes mask holes 12H, which are examples of through-holes. The mask holes 12H are defined by hole side surfaces, which have a semi-arcuate shape that tapers down from the front surface 12F toward the rear surface 12R.

The thickness of the mask plate 12 is, for example, between 1 μm and 15 μm inclusive. Such a thin mask plate 12 reduces the area in the vapor deposition target that is shadowed by the vapor deposition mask 10A as viewed from vapor deposition particles traveling toward the mask plate 12, in other words, reduces the shadow effect.

The mask plate 12 having a thickness of between 3 μm and 5 μm inclusive can have mask holes 12H that are spaced apart from one another in a plan view of the front surface 12F and used to manufacture a high-resolution display device having a resolution of between 700 ppi and 1000 ppi inclusive. The mask plate 12 having a thickness of between 5 μm and 10 μm inclusive can have mask holes 12H that are spaced apart from one another in a plan view of the front surface 12F and used to manufacture a medium-resolution display device having a resolution of between 400 ppi and 700 ppi inclusive. The mask plate 12 having a thickness of between 10 μm and 15 μm inclusive can have mask holes 12H that are spaced apart from one another in a plan view of the front surface 12F and used to manufacture a low-resolution display device having a resolution of between 300 ppi and 400 ppi inclusive.

In the mask holes 12H, each mask hole 12H may be continuous with its adjacent mask hole 12H in a plan view of the front surface 12F. In this case, the mask plate 12 having a thickness of between 5 μm and 10 μm inclusive can have mask holes 12H that are used to manufacture a high-resolution display device. Further, the mask plate 12 having a thickness of between 10 μm and 15 μm inclusive can have mask holes 12H that are used to manufacture a medium-resolution or high-resolution display device.

The front surface 12F includes front surface openings H1, which are openings of the mask holes 12H. The rear surface 12R includes rear surface openings H2, which are openings of the mask holes 12H. In a plan view of the front surface 12F, the front surface openings H1 are larger in size than the rear surface openings H2. Each mask hole 12H is a passage for the vapor deposition particles vaporized or sublimated from the vapor deposition source. The vapor deposition particles vaporized or sublimated from the vapor deposition source travel in the mask holes 12H from the front surface openings H1 toward the rear surface openings H2. The mask holes 12H with the front surface openings H1 that are larger than the rear surface openings H2 reduce the shadow effect for the vapor deposition particles entering through the front surface openings H1.

When the mask plate 12 has a thickness of between 3 μm and 5 μm inclusive, the mask holes 12H used to manufacture the above-described high-resolution display device can be formed simply by wet-etching the metal sheet used to form the mask plate 12 from the front surface of the metal sheet. When the mask plate 12 has a thickness of between 10 μm and 15 μm inclusive, the mask holes 12H used to manufacture the above-described low-resolution display device can be formed simply by wet-etching the metal sheet from the front surface of the metal sheet. In either case, it is not necessary to wet-etch the metal sheet from the rear surface of the metal sheet.

In contrast, if a thicker metal sheet is used to form a vapor deposition mask for the manufacturing of a display device having each of the high-, medium- and low resolutions, this metal sheet needs to be wet-etched from both the front surface and the rear surface of the metal sheet. When the metal sheet is wet-etched from both the front surface and the rear surface, each mask hole has a shape in which a front surface recess, which includes a front surface opening, and a rear surface recess, which includes a rear surface opening, are connected to each other in the thickness direction of the mask plate. In the mask hole, a section where the front surface recess is connected to the rear surface recess is referred to as a connection section. The area of the mask hole 12H in the direction parallel to the front surface 12F is smallest in the connection section. The distance between the connection section and the rear surface opening in the mask hole 12H is referred to as a step height. A greater step height increases the above-described shadow effect. The above-described mask plate 12 has zero step height. Thus, the mask plate 12 advantageously limits the shadow effect.

The mask plate 12 may include only one mask region 12a, which includes the mask holes 12H, or may include multiple mask regions 12a. When the mask plate 12 includes multiple mask regions 12a, the adjacent mask regions 12a are divided from each other by the surrounding region 12b, which does not include the mask holes 12H. In all of the mask plates 12 included in the vapor deposition mask 10A, the number of the mask regions 12a of each mask plate 12 may be the same. Alternatively, some of the mask plates 12 may have a first number of mask regions 12a, and some of the mask plates 12 may have a second number of mask regions 12a.

### Second Example

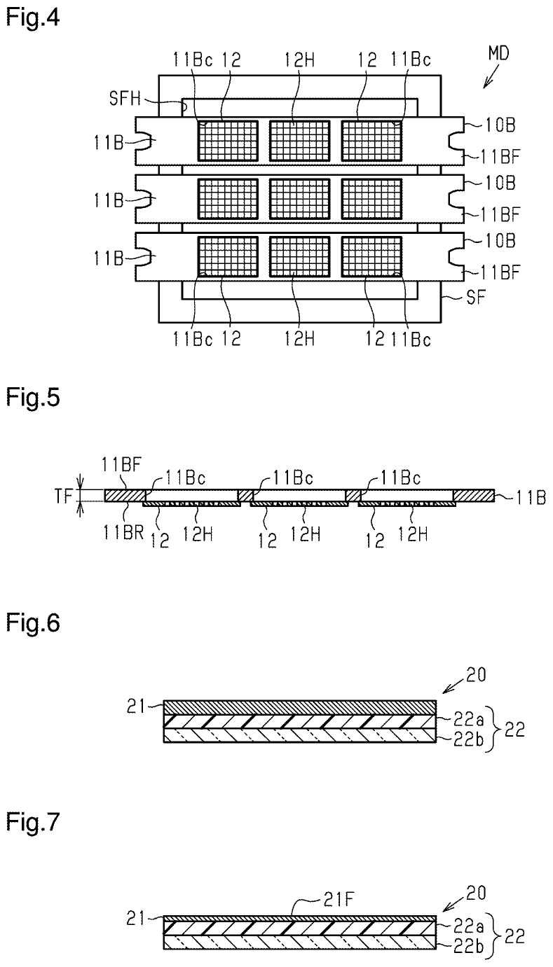

The second example of the vapor deposition mask will now be described with reference to FIGS. 4 to 5. The second example differs from the first example in the shape of the mask frame of the vapor deposition mask. Thus, in the following description, the differences of the second example from the first example will be described in detail and the features of the second example common to the first example will not be described.

As shown in FIG. 4, a vapor deposition mask 10B includes mask plates 12 and mask frames 11B. In a plan view of front surfaces 11BF, the mask frames 11B have the shape of a strip extending in one direction. The mask frames 11B are more rigid than the mask plates 12.

In the example shown in FIG. 4, the vapor deposition mask 10B includes the mask plates 12, and each mask frame 11B includes the same number of openings 11Bc as the mask plates 12. Since the mask plates 12 are laid out in a row in the extending direction of the mask frames 11B, the mask frames 11B have a ladder shape that can surround the mask plates 12. The vapor deposition mask 10B may include mask plates 12 laid out in two or more rows in the width direction of the mask frames 11B. In this case, the mask frames 11B also include openings 11Bc laid out in two or more rows in the width direction of the mask frames 11B.

In the same manner as the vapor deposition mask 10A, the mask plate 12 of the vapor deposition mask 10B may include only one mask region 12a, which includes the mask holes 12H, or may include multiple mask regions 12a. When the mask plate 12 includes multiple mask regions 12a, the adjacent mask regions 12a are divided from each other by the surrounding region 12b, which does not include the mask holes 12H. In all of the mask plates 12 included in the vapor deposition mask 10B, the number of the mask regions 12a of each mask plate 12 may be the same. Alternatively, some of the mask plates 12 may have a first number of mask regions 12a, and some of the mask plates 12 may have a second number of mask regions 12a.

The vapor deposition masks 10B and a support frame SF, which supports the vapor deposition mask 10B, form a mask device MD. In the example shown in FIG. 4, one mask device MD is formed by attaching multiple vapor deposition masks 10B to one support frame SF. The support frame SF has a rectangular shape. The mask plates 12 of each vapor deposition mask 10B are located in a region defined by a support frame hole SFH in the support frame SF. The support frame SF is thicker than the mask frame 11B. Thus, the thickness of the support frame SF causes the support frame SF to be more rigid than the mask frame 11B. The support frame SF may have a thickness of, for example, 10 mm and 30 mm inclusive.

FIG. 5 shows the structure of the cross-section of the vapor deposition mask 10B along the plane that is orthogonal to the front surface 11BF and parallel to the extending direction of the mask frame 11B.

As shown in FIG. 5, each opening 11Bc is a through-hole extending through the front surface 11BF and a rear surface 11BR of the mask frame 11B. Each opening 11Bc has a rectangular shape. Further, in each opening 11Bc, the rectangular cross-sectional shape is continuous in the width direction of the mask frame 11B. In the same manner as the opening 11Ac of the mask frame 11A in the first example, each opening 11Bc may have a trapezoid shape, an inverted-trapezoid shape, or an arcuate shape. The thickness TF of the mask frame 11B is greater than or equal to 20 μm. The thickness TF of the mask frame 11B may be less than or equal to 100 μm.

Method for Manufacturing Vapor Deposition Mask

The method for manufacturing the vapor deposition mask will now be described with reference to FIGS. 6 to 14.

In the method for manufacturing the vapor deposition mask 10A, 10B, a mask plate with mask holes is manufactured from a metal sheet made of iron-nickel alloy. The method includes preparing a metal sheet and a glass substrate, joining the glass substrate to the metal sheet, forming the mask plate from the metal sheet, joining the mask plate to a mask frame, and peeling off a plastic layer (described later) and the glass substrate from the mask plate.

In the preparing the metal sheet and the glass substrate, the absolute value of the difference between the linear expansion coefficient of the glass substrate and the linear expansion coefficient of the metal sheet is less than or equal to 1.3×10⁻⁶/° C. in a temperature range between 25° C. and 100° C. inclusive. In the joining the glass substrate to the metal sheet, the glass substrate is joined to the metal sheet with the plastic layer in between. In the forming the mask plate, the mask plate is formed from the metal sheet by forming mask holes in the metal sheet joined to the glass substrate. In the joining the metal sheet to the mask frame, a surface of the mask plate that is opposite to a surface in contact with the plastic layer is joined to the mask frame, which has a higher rigidity than the mask plate and has a shape that surrounds the mask holes. Subsequently, the plastic layer and the glass substrate are peeled off from the mask plate joined to the mask frame. The method for manufacturing the vapor deposition mask 10A, 10B will now be described in more detail with reference to the drawings.

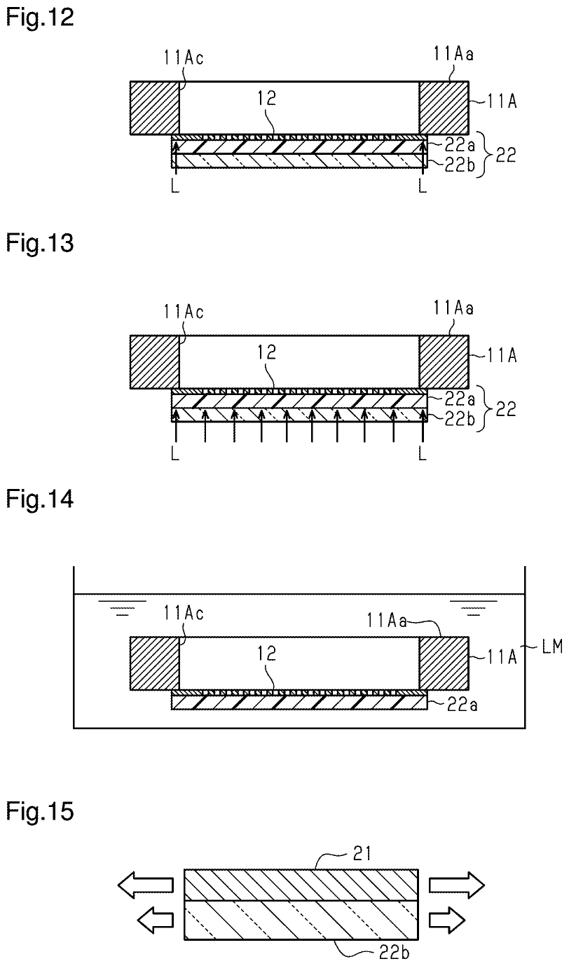

FIGS. 6 to 11 show a process that prepares a substrate used to form the mask plate 12 and a process that forms the mask plate 12. FIGS. 12 to 14 show a process that joins the mask plate 12 to the mask frame 11A and a process that peels off a support from the mask plate 12. To facilitate understanding, FIG. 12 to 14 illustrate the method for manufacturing the mask frame 11A of the vapor deposition mask 10A in the first example. The same manufacturing method is performed to manufacture the vapor deposition mask 10B when the mask frame 11B of the vapor deposition mask 10B in the second example is used. For illustrative purposes, FIGS. 12 to 14 show the structure in which the mask frame 11A includes only one opening 11Ac and the vapor deposition mask 10A includes one mask plate 12.

As shown in FIGS. 6 to 11, in the method for manufacturing the vapor deposition mask 10A, 10B, a substrate 20 is first prepared to form the mask plate 12 (refer to FIG. 6). The substrate 20 of the mask plate 12 includes a metal sheet 21, which forms the mask plate 12, and a support 22, which supports the metal sheet 21. The support 22 includes a plastic layer 22a and a glass substrate 22b. In the substrate 20, the plastic layer 22a is located between the metal sheet 21 and the glass substrate 22b.

In the temperature range between 25° C. and 100° C. inclusive, the absolute value of the difference between the linear expansion coefficient of the glass substrate 22b and the linear expansion coefficient of the metal sheet 21, which forms the mask plate 12, is less than or equal to 1.3×10⁻⁶/° C.

In the mask frame 11A of the vapor deposition mask 10A in the first example, when the mask frame 11A having a thickness of greater than or equal to 500 μm is used, it is preferred that the absolute value of the difference between the linear expansion coefficient of the glass substrate 22b and the linear expansion coefficient of the metal sheet 21 be less than or equal to 0.7×10⁻⁶/° C. When the absolute value of the difference between the two linear expansion coefficients is less than or equal to 0.7×10⁻⁶/° C., the mask plate 12 resists straining due to temperature changes in the glass substrate 22b and the mask plate 12 in the manufacturing process for the vapor deposition mask 10A. This prevents the releasing of the strains that occur in the mask plate 12 when the vapor deposition mask 10A is formed by the removal of the glass substrate 22b from the mask plate 12. Further, the mask plate 12 is joined to the mask frame 11A, which has a high rigidity. This prevents the displacement of the mask plate 12 from the mask frame 11A after the mask plate 12 is joined to the mask frame 11A. Accordingly, the position of each mask hole 12H relative to the vapor deposition target S is unlikely to change. As a result, the position accuracy of a pattern formed in the vapor deposition target S increases.

In the mask frame 11B of the vapor deposition mask 10B in the second example, when the mask frame 11B having a thickness of greater than or equal to 20 μm, it is preferred that the absolute value of the difference between the linear expansion coefficient of the glass substrate 22b and the linear expansion coefficient of the metal sheet 21 be less than or equal to 0.4×10⁻⁶/° C. This achieves an advantage equivalent to the advantage achieved when the thickness of the mask frame 11A is 500 μm and the absolute value of the difference between the linear expansion coefficient of the glass substrate 22b and the linear expansion coefficient of the metal sheet 21 is less than or equal to 0.7×10⁻⁶/° C.

Furthermore, when the metal sheet 21 and the glass substrate 22b are prepared, it is preferred that the glass substrate 22b having a smaller linear expansion coefficient than the metal sheet 21 be prepared in the temperature range between 25° C. and 100° C. inclusive.

As described above, the metal sheet 21 may be made of iron-nickel alloy. The glass substrate 22b may be made of a material selected from the group consisting of non-alkali glass, quartz glass, crystallized glass, borosilicate glass, high-silica glass, porous glass, and soda-lime glass. Thus, the absolute value of the difference between the linear expansion coefficient of the glass substrate 22b and the linear expansion coefficient of the mask plate 12 can be less than or equal to 1.3×10⁻⁶/° C. in the temperature range between 25° C. and 100° C. inclusive.

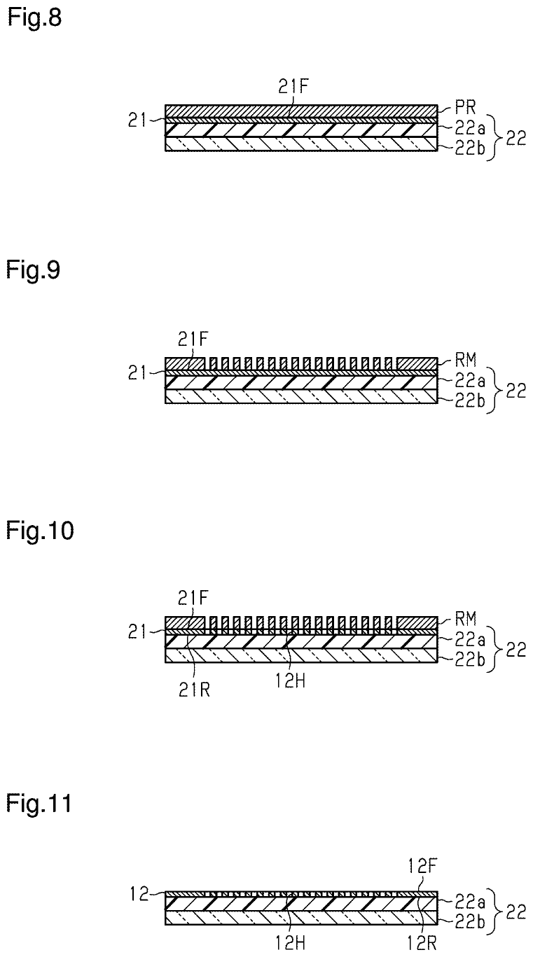

Next, the thickness of the metal sheet 21 is reduced by etching a front surface 21F of the metal sheet 21. For example, the thickness of the metal sheet 21 can be reduced to half or less of the thickness of the metal sheet 21 prior to being etched (refer to FIG. 7). Further, a resist layer PR is formed on the front surface 21F of the metal sheet 21 (refer to FIG. 8). The resist layer PR is exposed and developed, thereby forming a resist mask RM on the front surface 21F (refer to FIG. 9).

Then, the front surface 21F of the metal sheet 21 is wet-etched using the resist mask RM. This forms the mask holes 12H in the metal sheet 21 (refer to FIG. 10). In the wet etching of the metal sheet 21, the front surface openings H1 are formed in the front surface 21F, and the rear surface openings H2, which are smaller in size than the front surface openings H1, are then formed in the rear surface 21R. Subsequently, the resist mask RM is removed from the front surface 21F, completing the mask plate 12 (refer to FIG. 11). The front surface 21F of the metal sheet 21 corresponds to the front surface 12F of the mask plate 12. The rear surface 21R of the metal sheet 21 corresponds to the rear surface 12R of the mask plate 12.

The process that prepares the substrate 20 includes a process that sandwiches the plastic layer 22a between the metal sheet 21 and the glass substrate 22b and joins the metal sheet 21 to the glass substrate 22b with the plastic layer 22a in between. To join the metal sheet 21, the plastic layer 22a, and the glass substrate 22b to each other, a chemical bonding (CB) process is first performed for the surfaces of the metal sheet 21 and the glass substrate 22b that are in contact at least with the plastic layer 22a. The surfaces of the metal sheet 21 and the glass substrate 22b that are subjected to the CB process are target surfaces. In the CB process, for example, a chemical solution may be applied to the target surfaces to provide the target surfaces with a functional group reactive with the plastic layer 22a. The CB process applies, for example, silicon-containing compounds to the target surfaces.

The metal sheet 21, the plastic layer 22a, and the glass substrate 22b are layered in this order and then subjected to thermocompression bonding. The target surface of the metal sheet 21 and the target surface of the glass substrate 22b are brought into contact with the plastic layer 22a. Thus, the reaction of the functional group on the target surfaces with the functional group on the surfaces of the plastic layer 22a bonds the metal sheet 21 to the plastic layer 22a and bonds the glass substrate 22b to the plastic layer 22a.

The plastic layer 22a is preferably made of polyimide. This allows the metal sheet 21, the plastic layer 22a, and the glass substrate 22b to have similar linear expansion coefficients. Consequently, in the process that manufactures the vapor deposition mask 10A, 10B, the laminate of the metal sheet 21, the plastic layer 22a, and the glass substrate 22b is unlikely to warp when heated, which would be otherwise caused by a difference in thermal expansion coefficient between the layers of the laminate.

Electrolysis or rolling is used in the method for producing the metal sheet 21. The metal sheet 21 obtained through electrolysis or rolling may be subjected to post-treatment, such as polishing or annealing. When electrolysis is used to produce the metal sheet 21, the metal sheet 21 is formed on the surface of the electrode used for electrolysis. The metal sheet 21 is then removed from the surface of the electrode. The metal sheet 21 is thus produced. In the above-described joining step, the metal sheet 21 that is joined to the glass substrate 22b with the plastic layer 22a in between preferably has a thickness of greater than or equal to 10 μm. When rolling is used to produce the metal sheet 21, the metal sheet 21 preferably has a thickness of greater than or equal to 15 μm. When electrolysis is used to produce the metal sheet 21, the metal sheet 21 preferably has a thickness of greater than or equal to 10 μm.

The electrolytic bath for electrolysis contains an iron ion source, a nickel ion source, and a pH buffer. The electrolytic bath may also contain a stress relief agent, an Fe³⁺ ion masking agent, and a complexing agent, for example. The electrolytic bath is a weakly acidic solution having a pH adjusted for electrolysis. Examples of the iron ion source include ferrous sulfate heptahydrate, ferrous chloride, and ferrous sulfamate. Examples of the nickel ion source include nickel(II) sulfate, nickel(II) chloride, nickel sulfamate, and nickel bromide. Examples of the pH buffer include boric acid and malonic acid. Malonic acid also functions as an Fe³⁺ ion masking agent. The stress relief agent may be saccharin sodium, for example. The complexing agent may be malic acid or citric acid, for example. The electrolytic bath used for electrolysis may be, for example, an aqueous solution containing additives listed above. The electrolytic bath is adjusted using a pH adjusting agent to have a pH of between 2 and 3 inclusive, for example. The pH adjusting agent may be 5% sulfuric acid or nickel carbonate.

The conditions for electrolysis are set to achieve desired values of, for example, thickness and composition ratio of the metal sheet 21. These conditions include the temperature of the electrolytic bath, the current density, and the electrolysis duration. The anode used in the electrolytic bath may be a pure iron plate or a nickel plate, for example. The cathode used in the electrolytic bath may be a plate of stainless steel, such as SUS304. The temperature of the electrolytic bath may be between 40° C. and 60° C. inclusive. The current density may be between 1 A/dm² and 4 A/dm² inclusive, for example.

The composition of electrolytic solution and the conditions for electrolysis can be set, for example, as follows.

Ferrous sulfate heptahydrate: 83.4 g/L

Nickel(II) sulfate hexahydrate: 250.0 g/L

Nickel(II) chloride hexahydrate: 40.0 g/L

Boric acid: 30.0 g/L

Saccharin sodium dihydrate: 2.0 g/L

Malonic acid: 5.2 g/L

Temperature: 50° C.

The metal sheet 21 can be manufactured through electrolysis with other compositions and conditions.

When rolling is used to produce the metal sheet 21, a base material for manufacturing the metal sheet 21 is rolled. The rolled base material is annealed to obtain the metal sheet 21. In the formation of the base material, which is to be rolled to form the metal sheet 21, a deoxidizer (such as granular aluminum or granular magnesium) is mixed into the constituents of the base material for rolling so as to remove the oxygen trapped in the constituents. The aluminum and magnesium are contained in the base material as metallic oxide, such as an aluminum oxide and a magnesium oxide. While most of the metallic oxide is removed from the base material before rolling, some of the metallic oxide remains in the base material to be rolled. In this respect, the method for manufacturing the metal sheet 21 using electrolysis prevents the mixing of the metallic oxide into the metal sheet 21.

In the thinning step that reduces the thickness of the metal sheet 21 before the formation of the resist mask RM on the metal sheet 21, wet etching may be used. As described above, the thinning step preferably reduces the thickness of the metal sheet 21 subsequent to being thinned to half or less of the thickness of the metal sheet 21 prior to being thinned. This allows the metal sheet 21 to be at least twice as thick as the mask plate 12. Thus, even when the mask plate 12 is required to have a thickness of less than or equal to 15 μm as described above, the metal sheet 21 that has a higher rigidity than the mask plate 12 of the vapor deposition mask 10A, 10B is used before the metal sheet 21 is joined to the glass substrate 22b. This facilitates the joining of the metal sheet 21 to the glass substrate 22b as compared to a configuration in which the metal sheet 21 that is joined to the glass substrate 22b has the same thickness as the mask plate 12. The step that reduces the thickness of the metal sheet 21 may be omitted.

Acidic etchant may be used as the etchant for thinning the metal sheet 21 by wet-etching the metal sheet 21. When the metal sheet 21 is made of Invar, any etchant capable of etching Invar can be used. The acidic etchant may be a solution containing perchloric acid, hydrochloric acid, sulfuric acid, formic acid, or acetic acid mixed in a ferric perchlorate solution or a mixture of a ferric perchlorate solution and a ferric chloride solution. The front surface 21F may be etched using a dipping method, a spraying method, or a spinning method.

Acidic etchant may be used as an etchant to form the mask holes 12H in the metal sheet 21 by etching. When the metal sheet 21 is made of Invar, any of the etchants usable in the above-described thinning step can be used. In addition, any of the methods usable in the thinning step may be used to etch the mask holes 12H.

As described above, when the thickness of the metal sheet 21 is between 3 μm and 5 μm inclusive, the mask holes 12H can be formed such that 700 or more and 1000 or less mask holes 12H are arranged per inch in a plan view of the front surface 21F of the metal sheet 21. That is, a mask plate 12 is obtained that can be used to form a display device having a resolution of between 700 ppi and 1000 ppi inclusive.

As described above, when the thickness of the metal sheet 21 is between 5 μm and 10 μm inclusive, the mask holes 12H can be formed such that 400 or more and 700 or less mask holes 12H are arranged per inch in a plan view of the front surface 21F of the metal sheet 21. That is, a mask plate 12 is obtained that can be used to form a display device having a resolution of between 400 ppi and 700 ppi inclusive.

As described above, when the thickness of the metal sheet 21 is between 10 μm and 15 μm inclusive, the mask holes 12H can be formed such that 300 or more and 400 or less mask holes 12H are arranged per inch in a plan view of the front surface 21F of the metal sheet 21. That is, a mask plate 12 is obtained that can be used to form a display device having a resolution of between 300 ppi and 400 ppi inclusive.

The step that prepares the substrate 20 may include a step that thins the metal sheet 21 from one surface of the metal sheet 21 before joining the metal sheet 21, the plastic layer 22a, and the glass substrate 22b to each other. In this case, the thinning step included in the step that prepares the substrate 20 is a first thinning step, and the thinning step performed after the step that prepares the substrate 20 is a second thinning step.

In the first thinning step, the metal sheet 21 is thinned by etching the first surface. In the second thinning step, the metal sheet 21 is thinned by etching the second surface, which differs from the first surface. The surface formed by etching the first surface is the surface of the metal sheet 21 that is joined to the plastic layer 22a and also subjected to the CB process.

Etching both the first and second surfaces of the metal sheet 21 allows the residual stress of the metal sheet 21 to be adjusted from both the first and second surfaces. This limits imbalance in the residual stress of the metal sheet 21 after etching, as compared to a configuration that etches only one surface. Consequently, when the mask plate 12 obtained from the metal sheet 21 is joined to the mask frame 11A, 11B, the mask plate 12 is less likely to have creases. The surface of the metal sheet 21 that is obtained by etching the first surface corresponds to the rear surface 12R of the mask plate 12, and the surface obtained by etching the second surface corresponds to the front surface 12F of the mask plate 12.

The amount of etching the first surface of the metal sheet 21 is a first etching amount, and the amount of etching the second surface of the metal sheet 21 is a second etching amount. The first etching amount and the second etching amount may be the same or different. When the first etching amount differs from the second etching amount, the first etching amount may be larger than the second etching amount, or the second etching amount may be larger than the first etching amount. When the second etching amount is larger than the first etching amount, the amount of etching performed with the metal sheet 21 supported by the plastic layer 22a and the glass substrate 22b is larger. This increases the handleability of the metal sheet 21 and consequently facilitates the etching of the metal sheet 21.

In order to reduce the residual stress of the metal sheet 21 and to reduce the metallic oxide contained in the metal sheet 21 obtained by rolling, the first surface and the second surface are preferably both etched as described above. The first etching amount and the second etching amount may be, for example, greater than or equal to 3 μm.

As shown in FIGS. 12 to 14, part of the mask plate 12 is joined to part of the mask frame 11A (refer to FIG. 12). Multiple mask plates 12 are joined to a single mask frame 11A such that each mask plate 12 covers the corresponding opening 11Ac. The structure shown in FIG. 12 is an example of a vapor deposition mask intermediate. That is, the deposition mask intermediate includes the mask plate 12, the mask frame 11A, the plastic layer 22a, and the glass substrate 22b. In the vapor deposition mask intermediate, the absolute value of the difference between the linear expansion coefficient of the glass substrate and the linear expansion coefficient of the metal sheet is less than or equal to 1.3×10⁻⁶/° C. in the temperature range between 25° C. and 100° C. inclusive.

Then, the glass substrate 22b is peeled off from the plastic layer 22a (refer to FIG. 13). That is, the glass substrate 22b is removed from the plastic layer 22a. Next, the plastic layer 22a is peeled off from each mask plate 12 (refer to FIG. 14). That is, the plastic layer 22a is removed from each mask plate 12. The above-described vapor deposition mask 10A is thus obtained. Thus, the method for manufacturing the vapor deposition mask 10A includes joining the mask plates 12 to the mask frame 11A and then peeling off the support 22 from each mask plate 12.

In the process that joins part of the mask plate 12 to part of the mask frame 11A, the mask frame 11A is prepared. As described above, the mask frame 11A included in the vapor deposition mask 10A of the first example includes the frame-shaped portion 11Aa, the defining element 11Ab, and the openings 11Ac. To form the mask frame 11A, a metal sheet member is prepared. As described above, the plate member may be made of Invar or may be made of metal other than Invar. The metal other than Invar may be, for example, stainless steel. Subsequently, the openings 11Ac may be formed in the plate member. The openings 11Ac may be formed by wet etching and may be formed by cutting with the application of laser beams.

In the process that joins part of the mask plate 12 to part of the mask frame 11A, the front surface 12F of the mask plate 12 is joined to the mask frame 11A. As described above, the mask frame 11A is preferably made of iron-nickel alloy. The mask frame 11A may have a thickness of greater than or equal to 20 μm or greater than or equal to 500 μm.

As described above, laser welding can be used for the method for joining the mask plate 12 to the mask frame 11A. The section of the mask plate 12 corresponding to the joining section 10Aa is irradiated with laser beam L through the glass substrate 22b and the plastic layer 22a. Thus, the glass substrate 22b and the plastic layer 22a need to allow the laser beam L to pass through. In other words, the laser beam L needs to have a wavelength that can pass through the glass substrate 22b and the plastic layer 22a. An intermittent joining section 10Aa is formed by applying the laser beam L intermittently along the edge defining the opening 11Ac. A continuous joining section 10Aa is formed by applying the laser beam L continuously along the edge defining opening 11Ac. The mask plate 12 is thus welded to the mask frame 11A.

As described above, the method for manufacturing the vapor deposition mask 10A includes the step that peels off the support 22 from the mask plate 12. In the process that manufactures the vapor deposition mask 10A, the support 22 supports the mask plate 12 including the mask holes 12H. In the vapor deposition mask 10A, the mask frame 11A supports the mask plate 12. This allows the mask plate 12 to be thinner than that in a configuration in which the vapor deposition mask 10A is formed without using the support 22 and a configuration in which the mask plate 12 is supported by the above-described frame. Accordingly, the shortened distance from the front surface opening H1 to the rear surface opening H2 of each mask hole 12H improves the accuracy of the structure of the pattern formed using the vapor deposition mask 10A. In addition, in the method for manufacturing the vapor deposition mask 10A, the rigidity of the glass substrate 22b and the rigidity of the mask frame 11A improve the handleability of the mask plate 12.

The step that peels off the support 22 includes a first step and a second step. In the first step, the interface between the plastic layer 22a and the glass substrate 22b is irradiated with the laser beam L having a wavelength that passes through the glass substrate 22b and is absorbed by the plastic layer 22a. The glass substrate 22b is thus peeled off from the plastic layer 22a.

The first step applies the laser beam L to the interface between the plastic layer 22a and the glass substrate 22b so that the plastic layer 22a absorbs the heat energy of the laser beam L. This heats the plastic layer 22a and weakens the strength of the chemical bonding between the plastic layer 22a and the glass substrate 22b. The glass substrate 22b is then peeled off from the plastic layer 22a. In the first step, while the entire joining section 10Aa is preferably irradiated with the laser beam L, only a part of the joining section 10Aa may be irradiated with the laser beam L if the strength of bonding between the glass substrate 22b and the plastic layer 22a can be weakened in the entire joining section 10Aa.

At the wavelength of the laser beam L, the glass substrate 22b preferably has a higher transmittance than the plastic layer 22a. This increases the efficiency in heating the section of the plastic layer 22a that forms the interface between the glass substrate 22b and the plastic layer 22a, as compared to a configuration in which the glass substrate 22b has a lower transmittance than the plastic layer 22a.

When the wavelength of the laser beam L is, for example, between 308 nm and 355 nm inclusive, the glass substrate 22b preferably has a transmittance of greater than or equal to 54% and the plastic layer 22a preferably has a transmittance of less than or equal to 1% in this wavelength range. As a result, more than half the light quantity of the laser beam L applied to the glass substrate 22b passes through the glass substrate 22b, and the plastic layer 22a absorbs most of the laser beam L that has passed through the glass substrate 22b. This further increases the efficiency in heating the section of the plastic layer 22a that forms the interface between the glass substrate 22b and the plastic layer 22a.

As described above, the plastic layer 22a is preferably made of polyimide. The plastic layer 22a is preferably made of a colored polyimide. The glass substrate 22b is preferably transparent.

After the first step, the second step peels off the plastic layer 22a from the mask plate 12 by dissolving the plastic layer 22a using a chemical solution LM in the second step. The chemical solution LM may be a liquid that can dissolve the material of the plastic layer 22a and that is not reactive with the material of the mask plate 12. The chemical solution LM may be an alkaline solution, for example. The alkaline solution may be an aqueous sodium hydroxide solution, for example. In the example of FIG. 14, a dipping method is used to bring the plastic layer 22a into contact with the chemical solution LM. Instead, a spraying method and a spinning method may be used to bring the plastic layer 22a into contact with the chemical solution LM.

In the process that peels off the support 22 from the mask plate 12, the first step peels off the glass substrate 22b from the plastic layer 22a, and the second step peels off the plastic layer 22a from the mask plate 12. This reduces the external force acting on the mask plate 12, as compared to a configuration that applies external force to the laminate of the glass substrate 22b, the plastic layer 22a, and the mask plate 12 to cause interface failure to peel off the support 22 from the mask plate 12. As a result, the peeling of the support 22 is less likely to deform the mask plate 12, and ultimately less likely to deform the mask holes 12H in the mask plate 12.

Although the metal sheet 21, the plastic layer 22a, and the glass substrate 22b have similar linear expansion coefficients, the difference in the linear expansion coefficients is not negligible as described above. In this case, the linear expansion coefficient of the glass substrate 22b is preferably smaller than the linear expansion coefficient of the metal sheet 21. The advantage that will be described with reference to FIGS. 15 and 16 is thus achieved.

The difference between the linear expansion coefficient of the metal sheet 21 and the linear expansion coefficient of the glass substrate 22b will now be described with reference to FIGS. 15 and 16. For illustrative purposes, the plastic layer 22a is omitted in FIGS. 15 and 16. In the strain of the metal sheet 21 and the mask plate 12 that will be described later, the plastic layer 22a is much thinner than the glass substrate 22b in the substrate 20. Thus, the linear expansion coefficient of the plastic layer 22a affects the strain in a negligible manner.

As shown in FIG. 15, when the linear expansion coefficient of the metal sheet 21 is larger than the linear expansion coefficient of the glass substrate 22b (i.e., when the linear expansion coefficient of the glass substrate 22b is smaller than the linear expansion coefficient of the metal sheet 21), the metal sheet 21 extends relative to the glass substrate 22b. However, since the metal sheet 21 is fixed by the plastic layer 22a to the glass substrate 22b, which has a higher rigidity than the metal sheet 21, the deformation of the metal sheet 21 is limited by the glass substrate 22b. Cooling the laminate in this state shrinks the metal sheet 21 relative to the glass substrate 22b. However, in the same manner as heating, the deformation of the metal sheet 21 is limited by the glass substrate 22b. Thus, the metal sheet 21 includes strain that acts in a direction in which the metal sheet 21 shrinks.

As shown in FIG. 16, removing the glass substrate 22b from the mask plate 12 releases the mask plate 12 from the glass substrate 22b. This allows the mask plate 12 to deform. As described above, the metal sheet 21 includes strain that acts in the shrinking direction of the metal sheet 21. Thus, the mask plate 12, which is formed by etching the metal sheet 21, includes strain that acts in the shrinking direction of the mask plate 12. This causes the mask plate 12 to deform in the shrinking direction of the mask plate 12 by an amount corresponding to the difference between the linear expansion coefficient of the metal sheet 21 and the linear expansion coefficient of the glass substrate 22b.

When the mask frame 11A has a thickness of greater than or equal to 500 μm and the difference in the linear expansion coefficient is less than or equal to 0.7×10⁻⁶/° C., the deformation of the mask plate 12 is limited so as to limit the warpage of the mask plate 12 joined to the mask frame 11A and maintain the position accuracy of the mask holes 12H. When the mask frame 11B has a thickness of greater than or equal to 20 μm and the difference in the linear expansion coefficient is less than or equal to 0.4×10⁻⁶/° C., the deformation of the mask plate 12 is limited so as to limit the warpage of the mask plate 12 joined to the mask frame 11B and maintain the position accuracy of the mask holes 12H.

When the linear expansion coefficient of the metal sheet 21 is smaller than the linear expansion coefficient of the glass substrate 22b, heating the laminate causes the metal sheet 21 to accumulate the stress of the metal sheet 21 shrinking relative to the glass substrate 22b. When the laminate is cooled in this state, the metal sheet 21 includes strain acting in the direction in which the metal sheet 21 extends because the glass substrate 22b shrinks more than the metal sheet 21. When the mask plate 12 formed from such a metal sheet 21 is joined to the mask frame 11A, 11B and the glass substrate 22b is then peeled off from the mask plate 12, releasing the strain of the mask plate 12 deforms the mask plate 12 in its extending direction.

Even in this case, when the mask frame 11A has a thickness of greater than or equal to 500 μm and the difference in the linear expansion coefficient is less than or equal to 0.7×10⁻⁶/° C. as described above, the deformation of the mask plate 12 is limited so as to limit the warpage of the mask plate 12 joined to the mask frame 11A and maintain the position accuracy of the mask holes 12H. When the mask frame 11B has a thickness of greater than or equal to 20 μm and the difference in the linear expansion coefficient is less than or equal to 0.4×10⁻⁶/° C., the deformation of the mask plate 12 is limited so as to limit the warpage of the mask plate 12 joined to the mask frame 11B and maintain the position accuracy of the mask holes 12H.

Method for Manufacturing Display Device

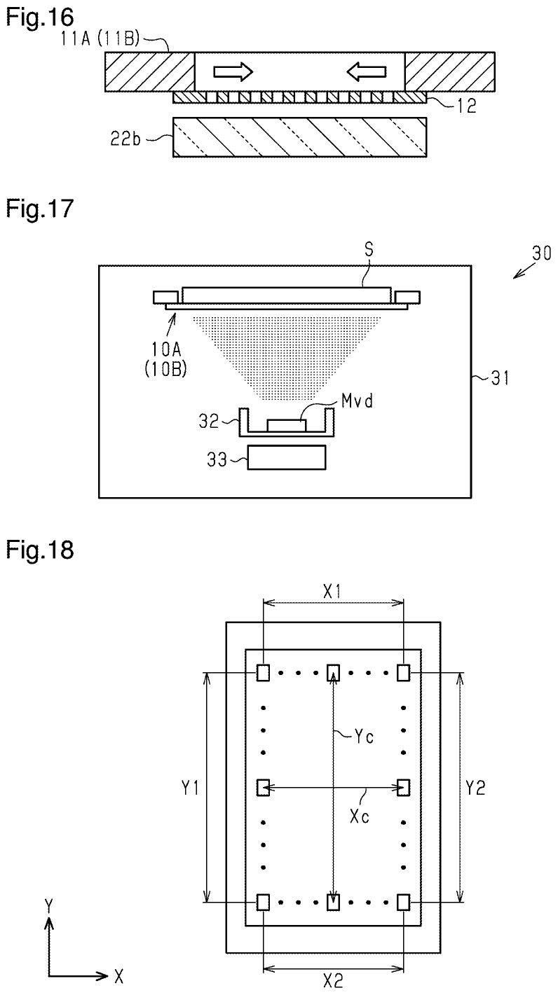

The method for manufacturing the display device will now be described with reference to FIG. 17.

The method for manufacturing the display device includes forming a pattern on the vapor deposition target S using the vapor deposition mask 10A, 10B manufactured by the method for manufacturing the vapor deposition mask 10A, 10B. With reference to the drawings, the process that forms a pattern will now be described with an example of the vapor deposition apparatus.

As shown in FIG. 17, a vapor deposition apparatus 30 includes an accommodation chamber 31, which accommodates the vapor deposition mask 10A, 10B and the vapor deposition target S. The accommodation chamber 31 is configured to hold the vapor deposition target S and the vapor deposition mask 10A, 10B at a predetermined position in the accommodation chamber 31. The accommodation chamber 31 includes a holder 32, which holds a vapor deposition material Mvd, and a heater 33, which heats the vapor deposition material Mvd. The vapor deposition material Mvd held by the holder 32 is an organic light-emitting material, for example. In the accommodation chamber 31, the vapor deposition target S and the vapor deposition mask 10A, 10B are located such that the vapor deposition mask 10A, 10B is located between the vapor deposition target S and the holder 32 and the vapor deposition mask 10A, 10B faces the holder 32. The vapor deposition mask 10A, 10B is arranged in the accommodation chamber 31 with the rear surface 12R of the mask plate 12 in close contact with the vapor deposition target S.

In the process that forms a pattern, the vapor deposition material Mvd is heated by the heater 33 so that the vapor deposition material Mvd is vaporized or sublimated. The vaporized or sublimated vapor deposition material Mvd passes through the mask holes 12H of the mask plate 12 of the vapor deposition mask 10A, 10B and adheres to the vapor deposition target S. This forms, on the vapor deposition target S, an organic layer having a shape that corresponds to the shapes and positions of the mask holes 12H of the vapor deposition mask 10A, 10B. The vapor deposition material Mvd may be a metal material for forming a pixel electrode included in a pixel circuit of a display layer, for example.

### TEST EXAMPLES

Test Examples will now be described with reference to FIG. 18.

### Test Example 1

A metal sheet was prepared that had a thickness of 40 μm, had the shape of a square with each side having a length of 152.4 mm, had a linear expansion coefficient of 1.2×10⁻⁶/° C. in the temperature range between 25° C. and 100° C. inclusive, and was made of Invar. Further, a glass substrate was prepared that had a thickness of 1.9 mm, had the shape of a square with each side having a length of 152.4 mm, had a linear expansion coefficient of 0.8×10⁻⁶/° C. in the temperature range between 25° C. and 100° C. inclusive, and was made of high-silica glass (VYCOR7913, manufactured by Corning Inc.). First, acid etchant was used to etch the entirety of one of the surfaces of the metal sheet. The thickness of the metal sheet was thus reduced by 17.5 μm. Then, the CB process was applied to the target surface of the metal sheet (the surface subsequent to being etched) and the target surface of the glass substrate to add silicon-containing compounds to the target surfaces. Further, a polyimide layer was prepared that had a thickness of 7.5 μm and had the shape of a square with each side having a length of 152.4 mm (Kapton® 30EN, manufactured by Du Pont-Toray Co. Ltd.).

The polyimide layer was held between the metal sheet and the glass substrate such that the target surfaces subjected to the CB process were in contact with the polyimide layer. Next, the metal sheet, the polyimide layer, and the glass substrate were layered in this order and then subjected to thermocompression bonding. In the thermocompression bonding, the pressurizing force was set to 4 MPa, the temperature was set to 250° C., and the pressurizing duration was set to 10 minutes.

Then, the acid etchant was used to etch the surface of the metal sheet opposite to the surface bonded to the polyimide layer. The thickness of the metal sheet was thus reduced by 17.5 μm, thereby reducing the thickness of the metal sheet to 5 μm. Next, a resist mask was formed on the front surface of the metal sheet. Subsequently, the acid etchant was used to form mask holes in the metal sheet. The mask holes having a square shape, each side having a length of 20 μm, were formed with a pitch of 40 μm in a plan view of the front surface of the metal sheet. In the metal sheet, mask holes were formed in a mask region having a width of 80 mm and a length of 130 mm whereas mask holes were not formed in a surrounding region that surrounds the mask region. In the following description, the width direction may be referred to as X-direction and the longitudinal direction may be referred to as Y-direction. The distance between the centers of the mask holes at the two ends in X-direction was set to 80 mm. The distance between the centers of the mask holes at the two ends in Y-direction was set to 130 mm. Further, the mask region was set for the metal sheet such that the center of the metal sheet coincided with the center of the mask region and each side of the metal sheet was parallel to one side of the mask region.

Through-holes were formed as alignment marks used to position the metal sheet relative to a frame. A rectangular reference region was set with a length of 90 mm in X-direction and with a length of 140 mm in Y-direction. The reference region was set such that the center of the reference region coincides with the center of the mask region. Further, four through-holes having a diameter of 50 μm were formed at the outside of the reference region. Each through-hole was formed at a position located outward from the corresponding one of the four corners of the reference region by 50 μm in X-direction and by 50 μm in Y-direction.

As a metal sheet for the frame, a metal sheet was prepared that had a thickness of 20 μm, had a rectangular shape with a width of 100 mm and a length of 180 mm, and was made of Invar. Next, the metal sheet was wet-etched so that an opening having a width of 90 mm and a length of 140 mm was formed in the metal sheet. The frame having a thickness of 20 μm was thus obtained. In the formation of the opening in the metal sheet, four alignment marks, each having a diameter of 30 μm, were formed through half-etching. Each alignment mark was formed at a position located outward from the corresponding one of the four corners of the opening by 50 μm in X-direction and by 50 μm in Y-direction.

Subsequently, the positions of the alignment marks of the metal sheet and the alignment marks of the frame were adjusted. By this adjustment, the position of the metal sheet was adjusted to the position of the frame such that the reference region of the metal sheet overlapped the opening of the frame. Then, laser welding was performed to join the mask plate to the frame. The entire mask plate in the peripheral direction was intermittently joined to the frame with a pitch of 0.5 mm. Further, in the laser welding, a fiber laser was used to emit a beam having a wavelength of between 1070 nm and 1100 nm inclusive. Subsequently, a laser beam having a wavelength of 355 nm was applied to the glass substrate and a plastic layer. As viewed from the glass substrate in the thickness direction, the laser beam was applied to the entire edge of the glass substrate. Then, the glass substrate was peeled off from the polyimide layer. A joined body of the frame and the mask plate was immersed in an aqueous sodium hydroxide solution to remove the plastic layer from the mask plate. The vapor deposition mask of Test Example 1 was thus obtained.

### Test Example 2

In Test Example 1, the glass substrate was changed to a quartz glass substrate having a thickness of 2.3 mm, having a square shape with each side having a length of 152.4 mm, and having a linear expansion coefficient of 0.5×10⁻⁶/° C. in the temperature range between 25° C. and 100° C. inclusive (SMS6009E5, manufactured by Shin-Etsu Chemical Co., Ltd.). Further, in Test Example 1, the thickness of the frame was changed to 100 μm. Other than these conditions, the same method as that of Test Example 1 was used to obtain the vapor deposition mask of Test Example 2.

### Test Example 3

In Test Example 2, the glass substrate was changed to a crystallized glass substrate having a thickness of 1.1 mm, having a square shape with each side having a length of 152.4 mm, and having a linear expansion coefficient of 0.1×10⁻⁶/° C. in the temperature range between 25° C. and 100° C. inclusive (Neoceram®, manufactured by Nippon Electric Glass Co., Ltd.). Other than this condition, the same method as that of Test Example 2 was used to obtain the vapor deposition mask of Test Example 3.

### Test Example 4

In Test Example 3, the glass substrate was changed to a non-alkali glass substrate having a linear expansion coefficient of 3.5×10⁻⁶/° C. in the temperature range between 25° C. and 100° C. inclusive (OA-10G, manufactured by Nippon Electric Glass Co., Ltd.). Other than this condition, the same method as that of Test Example 3 was used to obtain the vapor deposition mask of Test Example 4.

### Test Example 5

In Test Example 3, the glass substrate was changed to a crystallized glass substrate having a linear expansion coefficient of −0.1×10⁻⁶/° C. in the temperature range between 25° C. and 100° C. inclusive (Neoceram® N-0, manufactured by Nippon Electric Glass Co., Ltd.). Further, in Test Example 3, the metal sheet was changed to a substrate that had a linear expansion coefficient of 4.3×10⁻⁶/° C. in the temperature range between 25° C. and 100° C. inclusive and was made of Alloy 42, which is an iron-nickel alloy containing 42 mass % of nickel. Other than these conditions, the same method as that of Test Example 3 was used to obtain the vapor deposition mask of Test Example 5.

### Test Example 6

In Test Example 1, other than changing the thickness of the frame to 100 μm, the same method as that of Test Example 1 was used to obtain the vapor deposition mask of Test Example 6.

### Test Example 7

In Test Example 2, other than changing the thickness of the frame to 500 μm, the same method as that of Test Example 2 was used to obtain the vapor deposition mask of Test Example 7.

### Test Example 8

In Test Example 1, other than changing the thickness of the frame to 500 μm, the same method as that of Test Example 1 was used to obtain the vapor deposition mask of Test Example 8.

### Test Example 9

In Test Example 2, other than changing the thickness of the frame to 1500 μm, the same method as that of Test Example 2 was used to obtain the vapor deposition mask of Test Example 9.

### Test Example 10

In Test Example 3, other than changing the thickness of the frame to 1500 μm, the same method as that of Test Example 3 was used to obtain the vapor deposition mask of Test Example 10.

### Test Example 11

In Test Example 4, other than changing the thickness of the frame to 1500 μm, the same method as that of Test Example 4 was used to obtain the vapor deposition mask of Test Example 11.

### Test Example 12

In Test Example 5, other than changing the thickness of the frame to 1500 μm, the same method as that of Test Example 5 was used to obtain the vapor deposition mask of Test Example 12.

### Test Example 13

In Test Example 1, other than changing the thickness of the frame to 1500 μm, the same method as that of Test Example 1 was used to obtain the vapor deposition mask of Test Example 13.

Evaluation Method

The vapor deposition mask of each test example was visually observed. The cases where no warpage occurred in the mask plate of each vapor deposition mask were marked with “o”, and the case where warpage occurred in the mask plate of each vapor deposition mask were marked with “x”.

As shown in FIG. 18, a measurement device (CNC Video Measuring System VMR-6555 by Nikon Co.) was used to measure a first width X1 of a first short side, a second width X2 of a second short side, a first length Y1 of a first long side, and a second length Y2 of a second long side in each mask region. Each of the first width X1 and the second width X2 was set to the distance between the centers of the mask holes at the ends of the mask region in the extending direction of the first short side and the second short side. Each of the first length Y1 and the second length Y2 was set to the distance between the centers of the mask holes at the ends of the mask region in the extending direction of the first long side and the second long side. Further, a distance Yc between the center of the first short side and the center of the second short side and a distance Xc between the center of the first long side and the center of the second long side were measured.

The following equation was used to calculate a displacement amount ΔX for a specified value in X-direction, a displacement amount ΔY for a specified value in Y-direction, a displacement amount ΔXc for a specified value at the middle in X-direction, and a displacement amount ΔYc for a specified value at the middle in Y-direction. The cases where the absolute values of all the four values were less than or equal to 5 μm were marked with “∘”, and the cases where the absolute value of at least one of the four values were 5 μm were greater than 5 μm were marked with “x”.

ΔX={(X1−80000)+(X2−80000)}/2 (unit: μm)

ΔY={(Y1−130000)+(Y2−130000)}/2 (unit: μm)

ΔXc=Xc−80000 (unit: μm)

ΔYc=Yc−130000 (unit: μm)

The results of calculating the values are shown in the following Table 1. In each of the displacement amounts ΔX, ΔY, ΔXc, ΔYc, its negative value indicates that the measurement value is smaller than the specified value, and its positive value indicates that the measurement value is larger than the specified value.

TABLE 1

| | | Linear Expansion | | | | | | | | |
|---|---|---|---|---|---|---|---|---|---|---|
| | | Coefficient (×10⁻⁸/° C.) | | | | | | | | |
| | | | | Difference | | | | | | |
| | | | | between | | | | | | |
| | | | | Glass | | | | | | |
| | Frame | | | Substrate | | | | | | |
| | Thickness | Glass | Metal | and | | Position Accuracy (μm) | | | | |
| | (μm) | Substrate | sheet | Metal sheet | Appearance | ΔX | ΔY | ΔXc | ΔYc | Determination |
| Test | 20 | 0.8 | 1.2 | −0.4 | ○ | −3.7 | −4.4 | −4.9 | −3.8 | ○ |
| Example 1 | | | | | | | | | | |
| Test | 100 | 0.5 | 1.2 | −0.7 | x | −4.0 | −4.5 | −8.1 | −3.0 | x |
| Example 2 | | | | | | | | | | |
| Test | | −0.1 | 1.2 | −1.3 | x | −4.2 | −4.6 | −9.5 | −5.6 | x |
| Example 3 | | | | | | | | | | |
| Test | | 3.5 | 1.2 | 2.3 | x | 6.5 | 8.0 | 9.0 | 9.6 | x |
| Example 4 | | | | | | | | | | |
| Test | | −0.1 | 4.3 | −4.4 | x | −10.2 | −12.1 | −16.0 | −11.2 | x |
| Example 5 | | | | | | | | | | |
| Test | | 0.8 | 1.2 | −0.4 | ○ | −2.6 | −2.6 | −4.1 | −1.9 | ○ |
| Example 6 | | | | | | | | | | |
| Test | 500 | 0.5 | 1.2 | −0.7 | ○ | −3.5 | −3.0 | −4.7 | −2.3 | ○ |
| Example 7 | | | | | | | | | | |
| Test | | 0.8 | 1.2 | −0.4 | ○ | −1.9 | −2.1 | −2.9 | −1.5 | ○ |
| Example 8 | | | | | | | | | | |
| Test | 1500 | 0.5 | 1.2 | −0.7 | ○ | −0.3 | −2.7 | −3.8 | −2.0 | ○ |
| Example 9 | | | | | | | | | | |
| Test | | −0.1 | 1.2 | −1.3 | ○ | −3.1 | −3.4 | −4.6 | −3.4 | ○ |
| Example 10 | | | | | | | | | | |
| Test | | 3.5 | 1.2 | 2.3 | x | 6.0 | 6.5 | 7.5 | 7.3 | x |
| Example 11 | | | | | | | | | | |
| Test | | −0.1 | 4.3 | −4.4 | x | −7.0 | −6.8 | −9.4 | −7.0 | x |
| Example 12 | | | | | | | | | | |
| Test | | 0.8 | 1.2 | −0.4 | ○ | −0.5 | −1.1 | −2.2 | −1.2 | ○ |
| Example 13 | | | | | | | | | | |

As shown in Table 1, in Test Example 1, no warpage was visually observed in the mask plate. Further, in Test Example 1, all of the absolute values of the displacement amounts ΔX, ΔY, ΔXc, ΔYc were less than or equal to 5 am.

In Test Examples 2 to 5, warpage was visually observed in the mask plate regardless of the difference between the linear expansion coefficient of the glass substrate and the linear expansion coefficient of the metal sheet. Further, in Test Examples 2 to 5, at least one of the absolute values of the displacement amounts ΔX, ΔY, ΔXc, ΔYc was greater than 5 μm in Test Example 2. As is obvious from the measurement results of Test Examples 2 to 5, each of the displacement amounts ΔX, ΔY, ΔXc, ΔYc increases as the difference increases between the linear expansion coefficient of the glass substrate and the linear expansion coefficient of the metal sheet. In Test Example 6, no warpage was visually observed in the mask plate. Further, in Test Example 6, all of the absolute values of the displacement amounts ΔX, ΔY, ΔXc, ΔYc were less than or equal to 5 μm.

In Test Examples 7 and 8, no warpage was visually observed in the mask plate. Further, in Test Examples 7 and 8, all of the absolute values of the displacement amounts ΔX, ΔY, ΔXc, ΔYc were less than or equal to 5 μm.

In Test Examples 9, 10 and 13, no warpage was visually observed in the mask plate. Further, in Test Examples 9, 10, and 13, all of the absolute values of the displacement amounts ΔX, ΔY, ΔXc, ΔYc were less than or equal to 5 μm. In Test Examples 11 and 12, warpage was visually observed in the mask plate. Further, in Test Examples 11 and 12, all of the absolute values of the displacement amounts ΔX, ΔY, ΔXc, ΔYc were greater than 5 μm.

Such a result indicated that in the case of the frame having a thickness of 20 μm, warpage of the mask plate and displacement of the mask hole were prevented when the absolute value of the difference between the linear expansion coefficient of the glass substrate and the linear expansion coefficient of the metal sheet was less than or equal to 0.4×10⁻⁶/° C. In the case of the frame having a thickness of 500 μm, warpage of the mask plate and displacement of the mask hole were prevented when the absolute value of the difference between the linear expansion coefficient of the glass substrate and the linear expansion coefficient of the metal sheet was less than or equal to 0.7×10⁻⁶/° C. In the case of the frame having a thickness of 1500 μm, warpage of the mask plate and displacement of the mask hole were prevented when the absolute value of the difference between the linear expansion coefficient of the glass substrate and the linear expansion coefficient of the metal sheet was less than or equal to 1.3×10⁻⁶/° C.

In the vapor deposition mask with a frame having a rectangular shape, when the thickness of the frame and the difference between the linear expansion coefficient of the glass substrate and the linear expansion coefficient of the metal sheet are the same as those of Test Examples, the evaluation result tends to fall below that of each Test Example.

As described above, the method for manufacturing the vapor deposition mask, the method for manufacturing the display device, and the vapor deposition mask intermediate according to the embodiment provide the following advantages.

(1) The mask plate 12 is supported by the glass substrate 22b during the manufacturing of the vapor deposition mask 10A, 10B and supported by the mask frame 11A, 11B in the vapor deposition mask 10A, 10B. This improves the handleability of the mask plate 12.

(2) The mask frame 11A includes the defining element 11Ab having a grid pattern. Thus, the rigidity of the mask frame 11A is increased as compared to a configuration in which the frame has a rectangular shape. Further, the mask plates 12 are directly joined one by one to the surroundings of each opening 11Ac of the mask frame 11A, which has an increased rigidity. This limits the warpage of the mask plates 12 as compared to a structure in which a structural body supporting each mask plate 12 has the shape of a straight line extending one-dimensionally in the width direction of the mask plate, which has the shape of a planar strip. As a result, the position accuracy of a pattern formed in the vapor deposition target S increases.

(3) In the case of the mask frame 11A having a thickness of greater than or equal to 500 μm, the position accuracy of a pattern for the vapor deposition target S is increased when the absolute value of the difference between the linear expansion coefficient of the glass substrate 22b and the linear expansion coefficient of the metal sheet 21 is less than or equal to 0.7×10⁻⁶/° C.

(4) In the case of the mask frame 11B having a thickness of greater than or equal to m, the position accuracy of a pattern formed on the vapor deposition target S is increased when the absolute value of the difference between the linear expansion coefficient of the glass substrate 22b and the linear expansion coefficient of the metal sheet 21 is less than or equal to 0.4×10⁻⁶/° C.

(5) When the linear expansion coefficient of the glass substrate 22b is smaller than the linear expansion coefficient of the metal sheet 21, the displacement of the mask plate 12 from the mask frame 11A, 11B is prevented by the mask frame 11A and the warpage of the mask plate 12 is prevented.

The above-described embodiment may be modified as follows.

First Example of Vapor Deposition Mask

In the first example of the vapor deposition mask 10A, the vapor deposition mask 10A may be attached to a support frame that supports the vapor deposition mask 10A. In this case, the vapor deposition mask 10A is mounted on the vapor deposition apparatus with the vapor deposition mask 10A attached to the support frame.

Method for Manufacturing Vapor Deposition Mask

The thickness of the mask frame 11A in the vapor deposition mask 10A may be smaller than 500 μm. Even in this case, as long as the mask frame 11A has a configuration in which the grid-pattern defining element 11Ab is included in the region surrounded by the frame-shaped portion 11Aa, the advantage similar to the above-described advantage (2) is gained. Further, when the mask frame 11A has a thickness of greater than or equal to 20 μm and the absolute value of the difference between the linear expansion coefficient of the glass substrate 22b and the linear expansion coefficient of the metal sheet 21 is less than or equal to 0.4×10⁻⁶/° C., the advantage similar to the above-described advantage (4) is gained.

The thickness of the mask frame 11B in the vapor deposition mask 10B may be smaller than 20 μm as long as the mask frame 11B has a higher rigidity than the mask plate 12. Further, the mask frame 11B may have a thickness of greater than or equal to 500 μm. In this case, when the absolute value of the difference between the linear expansion coefficient of the glass substrate 22b and the linear expansion coefficient of the metal sheet 21 is less than or equal to 0.7×10⁻⁶/° C., the advantage similar to the above-described advantage (3) is gained.

1. A method for manufacturing a vapor deposition mask from a metal sheet made of iron-nickel alloy, the vapor deposition mask including a mask plate with mask holes, the method comprising:
preparing the metal sheet and a glass substrate in which an absolute value of a difference between a linear expansion coefficient of the glass substrate and a linear expansion coefficient of the metal sheet is less than or equal to 1.3×10⁻⁶/° C. in a temperature range between 25° C. and 100° C. inclusive;
joining the glass substrate to the metal sheet with a plastic layer in between;
forming the mask plate from the metal sheet by forming the mask holes in the metal sheet joined to the glass substrate;
joining, to a mask frame, a surface of the mask plate that is opposite to a surface in contact with the plastic layer, the mask frame having a higher rigidity than the mask plate and having a shape that surrounds the entire mask holes; and
removing the plastic layer and the glass substrate from the mask plate joined to the mask frame.

2. The method according to claim 1, wherein
the absolute value of the difference between the linear expansion coefficient of the glass substrate and the linear expansion coefficient of the metal sheet is less than or equal to 0.7×10⁻⁶/° C., and
the mask frame has a thickness of greater than or equal to 500 μm.

3. The method according to claim 1, wherein
the absolute value of the difference between the linear expansion coefficient of the glass substrate and the linear expansion coefficient of the metal sheet is less than or equal to 0.4×10⁻⁶/° C., and
the mask frame has a thickness of greater than or equal to 20 μm.

4. The method according to claim 1, wherein the linear expansion coefficient of the glass substrate is smaller than the linear expansion coefficient of the metal sheet.

5. The method according to claim 1, wherein the glass substrate is made of a material selected from the group consisting of non-alkali glass, quartz glass, crystallized glass, borosilicate glass, high-silica glass, porous glass, and soda-lime glass.

6. The method according to claim 1, comprising forming mask plates, wherein
openings are formed in the mask frame,
the joining the mask plate to the mask frame includes joining the mask plates to a single mask frame such that each of the mask plates covers a corresponding one of the openings, and
the mask frame includes a frame-shaped portion located at an outer edge of the mask frame to surround a vapor deposition target, a grid-pattern defining element located in a region surrounded by the frame-shaped portion, and the openings defined by the defining element.

7. A method for manufacturing a display device, the method comprising forming a pattern on a vapor deposition target using a vapor deposition mask manufactured by the method for manufacturing the vapor deposition mask according to claim 1.

8. A vapor deposition mask intermediate, comprising:
an iron-nickel alloy mask plate with mask holes, the mask plate including a first surface and a second surface opposite to the first surface;
a mask frame that having a higher rigidity than the mask plate and having a shape that surrounds the entire mask holes in the mask plate, the mask frame being joined to the first surface of the mask plate;
a plastic layer joined to the second surface of the mask plate; and
a glass substrate joined to the plastic layer, wherein
an absolute value of a difference between a linear expansion coefficient of the glass substrate and a linear expansion coefficient of the metal sheet is less than or equal to 1.3×10⁻⁶/° C. in a temperature range between 25° C. and 100° C. inclusive.
